(19) United States
(12) Patent Application Publication
(10) Pub. No.: US 2026/0023328 A1
(43) Pub. Date: Jan. 22, 2026

(54) LITHOGRAPHY APPARATUS AND METHOD FOR OPERATING A LITHOGRAPHY APPARATUS

(71) Applicant: Carl Zeiss SMT GmbH, Oberkochen (DE)

(72) Inventors: Stefan WALZ, Schwaebisch Gmuend (DE); Markus HOLZ, Aalen (DE); Oliver HERBST, Aalen (DE); Steffen VAAS, Ellwangen (DE)

(21) Appl. No.: 19/344,600

(22) Filed: Sep. 30, 2025

Related U.S. Application Data
(63) Continuation of application No. PCT/EP2024/059827, filed on Apr. 11, 2024.

(30) Foreign Application Priority Data
Apr. 13, 2023 (DE) 10 2023 203 339.9

(51) Int. Cl. G03F 7/00; G01B 7/30; G02B 26/10

(52) U.S. Cl. CPC G03F 7/70591; G01B 7/30; G02B 26/101; G03F 7/70116; G03F 7/7015; G03F 7/70508; G03F 7/70516; G03F 7/7085; G03F 7/70991

(57) ABSTRACT

A lithography apparatus comprises: a radiation source for creating radiation with a specific repetition frequency; and a MEMS mirror which is displaceable through a tilt angle in at least two tilt axes and serves to guide the radiation in the lithography apparatus. The mirror comprises a capacitive sensor comprising electrodes that capture the tilt angle. Four sensor units are provided per tilt axis for capturing a respective measurement signal from the capacitive sensor. A first pair of the sensor units excites the capacitive sensor with a first excitation signal and receives as a response a respective measurement signal. A second pair of the sensor units excites the capacitive sensor with a second excitation signal and receives as a response a respective measurement signal. The first and second excitation signals have opposite polarities. An evaluation unit determines the position of the MEMS mirror using the measurement signals.

### CROSS-REFERENCE TO RELATED APPLICATIONS

The present application is a continuation of, and claims benefit under 35 USC 120 to, international application No. PCT/EP2024/059827, filed Apr. 11, 2024, which claims benefit under 35 USC 119 of German Application No. 10 2023 203 339.9, filed Apr. 13, 2023. The entire disclosure of each of these applications is incorporated by reference herein.

### FIELD

The present disclosure relates to a lithography apparatus and to a method for operating a lithography apparatus.

### BACKGROUND

Microlithography is used to produce microstructured components, such as for example integrated circuits. The microlithography process is carried out using a lithography apparatus comprising an illumination system and a projection system. The image of a mask (reticle) illuminated via the illumination system is projected via the projection system onto a substrate, for example a silicon wafer, which is coated with a light-sensitive layer (photoresist) and is arranged in the image plane of the projection system, in order to transfer the mask structure to the light-sensitive coating of the substrate.

Driven by the desire for ever smaller structures in the production of integrated circuits, EUV lithography apparatuses which use light at a wavelength in the range of 0.1 nm to 30 nm, for example 13.5 nm, are currently being developed. Since most materials absorb light at this wavelength, such EUV lithography apparatuses typically use reflective optical units, i.e. mirrors, instead of refractive optical units, i.e. lens elements, as used previously.

The use of what are referred to as MEMS mirrors in an illumination system of a lithography apparatus is known. “MEMS” stands for “microelectromechanical system”. Such MEMS mirrors comprise what is known as a micromirror (also referred to as mirror plate) and an actuator. The actuator allows the alignment of the micromirror to be changed. During operation of the lithography apparatus, radiation (also referred to as operating light, for example EUV light) is incident on the surface of the micromirror and is reflected there. Changing the alignment of the micromirror makes it possible to influence the path taken by the EUV light through the illumination system. Such MEMS mirrors are generally manufactured on a substrate in integrated fashion. Such systems can use relatively little installation space. Accordingly, however, there are also often considerable limitations on the installation space for electronic components in a region behind the MEMS mirrors, i.e. on the side facing away from the operating light.

The micromirrors can be, e.g., secured to a carrier plate and configured to be at least partially manipulable or tiltable in order to allow a movement of a respective micromirror in up to six degrees of freedom and hence allow a highly accurate positioning of the micromirrors in relation to one another, for example in the pm range. This can allow changes in the optical properties that occur for instance during the operation of the lithography apparatus, e.g., as a result of thermal influences, to be corrected.

For the purposes of displacing the micromirrors, for example in the six degrees of freedom, actuators that are actuated by way of a control loop can be assigned to the micromirrors. A device for monitoring the tilt angle of a respective mirror can be provided as part of the control loop.

For example, WO 2009/100856 A1 discloses a facet mirror that is for a projection exposure apparatus of a lithography apparatus and comprises a multiplicity of individually displaceable individual mirrors. To ensure the optical quality of a projection exposure apparatus, relatively precise positioning of the displaceable individual mirrors is used. Furthermore, document DE 10 2013 209 442 A1 describes that the field facet mirror can be embodied as a microelectromechanical system (MEMS).

### SUMMARY

The photons from the EUV radiation source in the lithography apparatus may trigger the emission of electrons from the mirror surfaces of the MEMS mirrors as a result of the photoelectric effect. This can bring about temporally and spatially varying current flows over the MEMS mirrors of the field facet mirror. These temporally and spatially varying current flows over the MEMS mirrors may significantly disturb the monitoring of the tilt angle of the respective mirror.

The present disclosure seeks to provide an improved lithography apparatus.

According to a first aspect, a lithography apparatus is proposed. The lithography apparatus has a radiation source for generating radiation having a specific repetition frequency, a MEMS mirror which is displaceable by a tilt angle in at least two tilt axes and serves for guiding the radiation in the lithography apparatus, which mirror comprises a capacitive sensor having a number of electrodes for capturing the tilt angle, wherein four sensor units are provided per tilt axis for the purpose of capturing a respective measurement signal from the capacitive sensor, wherein a first pair of the four sensor units is configured to excite the capacitive sensor via a first excitation signal and to receive in response thereto a respective measurement signal, wherein a second pair of the four sensor units is configured to excite the capacitive sensor via a second excitation signal and to receive in response thereto a respective measurement signal, wherein the first excitation signal and the second excitation signal have opposite polarities, and an evaluation unit configured to determine the position of the MEMS mirror via the measurement signals of the four sensor units.

The first excitation signal and the second excitation signal have opposite polarities, in this case for example different signs, but can have identical amplitudes. Despite the two pairs of sensor units being excited by excitation signals having opposite polarities, the disturbance caused by the radiation incident on the MEMS mirror at the output of the first sensor units can have the same sign as the disturbance caused by the radiation incident on the MEMS mirror at the output of the second pair of sensor units. The sign of the disturbance does not change as a result of different signs of the excitation signals. Subtraction of two identical disturbances in the downstream processing stage can allow these disturbances to be taken into account by the evaluation unit in the determination of the position of the MEMS mirror in such a way that they cancel one another out.

When the excitation signals between the first and second pairs of the four sensor units have different signs, the two used output signals can also have different signs.

The processing in the downstream subtraction stage can result in the addition of both used signals. If the evaluation unit is embodied as a differential evaluation unit, it can subtract the output signal of the first pair of sensor units from the output signal of the second pair of sensor units, with the result that the disturbances having different signs may cancel one another out.

Hence, the effects of the disturbances, caused by the electrons dislodged by the radiation of the radiation source on the mirror plate, on the determination of the tilt angle of the mirror plate can be significantly reduced. This reduction of the disturbances can help allow the position of the mirror to be determined much more precisely. A more precise determination of the position of the mirror significantly can help improve the control loop for the control of the actuators (also referred to as control units) of the micromirrors.

The first pair of sensor units and the second pair of sensor units can have, for example, disjoint sets of sensor units.

The lithography apparatus or projection exposure apparatus can be an EUV lithography apparatus. EUV stands for “extreme ultraviolet” and denotes a wavelength of the operating light of between 0.1 nm and 30 nm. The lithography apparatus or projection exposure apparatus can also be a DUV lithography apparatus. DUV stands for “deep ultraviolet” and denotes a wavelength of the operating light of between 30 nm and 250 nm. The guided radiation can be EUV or DUV light.

According to an embodiment, the evaluation unit is embodied as a differential evaluation unit. The differential evaluation unit is configured for example in such a way that it subtracts the output signal of the first pair of sensor units from the output signal of the second pair of sensor units, with the result that the disturbances having the same sign at the outputs of the pairs of sensor units cancel one another out.

According to an embodiment, the evaluation unit comprises:
a first converter configured to receive the measurement signals I_{S1}, I_{S3} of the first pair of the sensor units and to provide on the output side a first voltage signal U₁ proportional to a difference between the received measurement signals I_{S1}, I_{S3};
a second converter configured to receive the measurement signals I_{S2}, I_{S4} of the second pair of the sensor units and to provide on the output side a second voltage signal U₂ proportional to a difference between the received measurement signals I_{S2}, I_{S4}; and
a subtractor configured to subtract the second voltage signal U₂ from the first voltage signal U₁ and depending thereon to output a difference signal Up on the output side.

According to an embodiment, the first converter is embodied as a first capacitance-voltage converter. The first capacitance-voltage converter is configured to obtain a first current I_{S1} at an input connected to the first sensor unit, which first current corresponds (I_{S1}=I_{AS1}+I_{SS1}) to a sum of the current I_{AS1} arising at the output of the first sensor unit owing to an excitation of the capacitive sensor with the first excitation signal V₁ and the current I_{SS1} arising at the output of the first sensor unit owing to a disturbance caused by the radiation on the MEMS mirror, to obtain a third current I_{S3} at an input connected to the third sensor unit, which third current corresponds (I_{S3}=I_{AS3}+I_{SS3}) to a sum of the current I_{AS3} arising at the output of the third sensor unit owing to an excitation of the capacitive sensor with the first excitation signal V₁ and the current (I_{SS3}) arising at the output of the third sensor unit owing to a disturbance caused by the radiation on the MEMS mirror, and to determine the first voltage signal U₁ according to the equation

$${U}_{1} = \frac{{\int }_{t 0}^{t 1} ( {I}_{AS 1} + {I}_{SS 1} ) dt}{{C}_{INT}} - \frac{{\int }_{t 0}^{t 1} ( {I}_{AS 3} + {I}_{SS 3} ) dt}{{C}_{INT}} \qquad ( 1 )$$

and to output the first voltage signal.

In this case, C_{INT} denotes the capacitance of the first capacitance-voltage converter. In the reference sign I_{AS1}, I denotes an electric current, A denotes an excitation and S₁ denotes the first sensor unit of the four sensor units. In the reference sign I_{SS1}, I denotes an electric current, S denotes a disturbance caused by the disturbing voltage V_{S} and S₁ denotes the first sensor unit. In the reference sign I_{AS3}, I denotes an electric current, A denotes an excitation and S₃ denotes the third sensor unit of the four sensor units. In the reference sign I_{SS3}, I denotes an electric current, S denotes a disturbance caused by the disturbing voltage V_{S} and S₃ denotes the third sensor unit. The disturbing voltage V_{S} arises on the mirror surface of the MEMS mirror by virtue of the incident radiation dislodging electrons on the mirror surface of the MEMS mirror. Die disturbing voltage V_{S} causes the abovementioned disturbances at the respective output of the sensor units.

If the electric charges are considered instead of the electric currents I_{S1}, I_{S3}, then equation (1) above is also representable by equation (2) below.

$${U}_{1} = \frac{{Q}_{S 1} - {Q}_{S 3}}{{C}_{INT}} + \frac{{Q}_{SS 1} - {Q}_{SS 3}}{{C}_{INT}} \qquad ( 2 )$$

In this case, Q_{S1} denotes the charge provided at the output of the first sensor unit S₁ owing to the excitation with the first excitation signal V₁, Q_{S3} denotes the charge provided at the output of the third sensor unit S₃ owing to the excitation with the first excitation signal V₁, Q_{SS1} denotes the charge provided at the output of the first sensor unit S₁ on account of the disturbing voltage V_{S}, and Q_{SS3} denotes the charge provided at the output of the third sensor unit S₃ owing to the disturbing voltage V_{S}.

According to an embodiment, the second converter is embodied as a second capacitance-voltage converter. The second capacitance-voltage converter is configured to obtain a second current I_{S2} at an input connected to the second sensor unit, which second current corresponds (I_{S2}=I_{AS2}+I_{SS2}) to a sum of the current I_{AS2} arising at the output of the second sensor unit owing to an excitation of the capacitive sensor with the second excitation signal V₂ and the current I_{SS2} arising at the output of the second sensor unit owing to a disturbance caused by the radiation on the MEMS mirror, to obtain a fourth current I_{S4} at an input connected to the fourth sensor unit, which fourth current corresponds (I_{S4}=I_{AS4}+I_{SS4}) to a sum of the current I_{AS4} arising at the output of the fourth sensor unit owing to an excitation of the capacitive sensor with the second excitation signal V₂ and the current I_{SS4} arising at the output of the fourth sensor unit owing to a disturbance caused by the radiation on the MEMS mirror, and to determine the second voltage signal U₂ according to the equation

$${U}_{2} = - \frac{{\int }_{t 0}^{t 1} ( {I}_{AS 2} + {I}_{SS 2} ) dt}{{C}_{INT}} - \frac{{\int }_{t 0}^{t 1} ( {I}_{AS 4} + {I}_{SS 4} ) dt}{{C}_{INT}} \qquad ( 3 )$$

and to output the first voltage signal.

In this case, C_{INT} denotes the capacitance of the second capacitance-voltage converter. In the reference sign I_{AS2}, I denotes an electric current, A denotes an excitation and S₂ denotes the second sensor unit of the four sensor units. In the reference sign I_{SS2}, I denotes an electric current, S denotes a disturbance caused by the disturbing voltage V_{S} and S₂ denotes the second sensor unit. In the reference sign I_{AS4}, I denotes an electric current, A denotes an excitation and S₄ denotes the fourth sensor unit of the four sensor units. In the reference sign I_{SS4}, I denotes an electric current, S denotes a disturbance caused by the disturbing voltage V_{S} and S₄ denotes the fourth sensor unit.

If the electric charges are considered instead of the electric currents I_{S2}, I_{S4}, then equation (3) above is also representable by equation (4) below.

$${U}_{2} = \frac{{Q}_{S 2} - {Q}_{S 4}}{{C}_{INT}} + \frac{{Q}_{SS 2} - {Q}_{SS 4}}{{C}_{INT}} \qquad ( 4 )$$

The subtractor is configured to subtract the second voltage signal U₂ from the first voltage signal U₁ and depending thereon to output a difference signal Up on the output side:

$${U}_{D} = {U}_{1} - {U}_{2} \qquad ( 5 )$$

Assuming that the disturbances caused by the incident radiation (i.e. the respective disturbing voltages V_{S}) on the mutually adjacent sensor units S₁-S₄ are identical or approximately identical, the charges Q_{SS1}, Q_{SS2}, Q_{SS3} and Q_{SS4} are identical or almost identical. U_{D} can then be calculated as follows by way of equation (6) below:

$$\begin{matrix}{U}_{D} = {U}_{1} - {U}_{2} \\ = \frac{{Q}_{S 1} - {Q}_{S 3}}{{C}_{INT}} + \frac{{Q}_{SS 1} - {Q}_{SS 3}}{{C}_{INT}} + \frac{{Q}_{S 2} - {Q}_{S 4}}{{C}_{INT}} - \frac{{Q}_{SS 2} - {Q}_{SS 4}}{{C}_{INT}} \\ = \frac{{Q}_{S 1} - {Q}_{S 3}}{{C}_{INT}} + \frac{{Q}_{S 2} - {Q}_{S 4}}{{C}_{INT}}\end{matrix} \qquad ( 6 )$$

As shown by equation (6), the difference signal U_{D} has no signal components attributable to the disturbing voltage V_{S}, accordingly no Q_{SS1}, no Q_{SS2}, no Q_{SS3} and no Q_{SS4}. The evaluation unit can then determine the position of the MEMS mirror very precisely using the difference signal U_{D}.

According to an embodiment, a first A/D converter (analog/digital converter) and a first weighting unit are connected downstream of the first converter. In this case, the first A/D converter is configured to convert the first voltage signal provided by the first converter into a first digital voltage signal. The first weighting unit is configured to weight the digital first voltage signal via an actual tilt angle—measured by a measuring unit—of the MEMS mirror in order to output a weighted first voltage signal. Furthermore, a second A/D converter and a second weighting unit are connected downstream of the second converter. In this case, the second A/D converter is configured to convert the second voltage signal provided by the second converter into a digital second voltage signal. The second weighting unit is configured to weight the digital second voltage signal via the actual tilt angle—measured by the measuring unit—of the MEMS mirror in order to output a weighted second voltage signal. In this case, the subtractor is configured to subtract the weighted second voltage signal from the weighted first voltage signal and depending thereon to output the difference signal on the output side.

The first A/D converter converts the first voltage signal into a first digital voltage signal. The first weighting unit weights the digital first voltage signal via the measured actual tilt angle of the MEMS mirror. The various MEMS mirrors of a micromirror array may have slight deviations with regard to their tilt angles. The measuring unit is provided in regard to this, the measuring unit measuring the respective actual tilt angle of the respective MEMS mirror. The measuring unit can comprise a laser for measuring the actual tilt angle of the MEMS mirror. The use of the first weighting unit makes it possible to take account of such tolerances. The second A/D converter and the second weighting unit operate in a corresponding fashion. The second A/D converter converts the second voltage signal into a digital second voltage signal and the second weighting unit weights this digital second voltage signal via the measured actual tilt angle. This individual adjustment enables tolerances to be taken into account, with the result that the suppression of the EUV disturbance is further improved.

According to an embodiment, the first converter and the second converter each comprise a trimmable capacitor. Furthermore, the lithography apparatus has a calibration unit configured to trim the respective trimmable capacitor via an actual tilt angle—measured by a measuring unit—of the MEMS mirror.

The trimming of the respective trimmable capacitor of the first converter and the second converter depending on the measured actual tilt angle of the MEMS mirror makes it possible to individually adjust tolerances, whereby the suppression of the EUV disturbance is further improved.

According to an embodiment, the MEMS mirror has a mirror plate that is displaceable by the tilt angle, a carrier plate for carrying the mirror plate, a base plate, a flexure that couples the base plate and the carrier plate and serves for tilting the mirror plate, and the capacitive sensor.

The individual plates are produced from polysilicon, for example. Doping gives rise to conductive elements, the electrodes. The mirror plate arises as a result of the polysilicon being coated with EUV-reflecting materials. The shielding plate can be produced from two plates of doped and undoped polysilicon, or by metallization of an undoped plate.

According to an embodiment, the capacitive sensor has an upper electrode arranged in the direction of the mirror plate and a lower electrode arranged in the direction of the base plate for measuring the tilt angle of the mirror plate of the MEMS mirror.

According to an embodiment, the electrodes of the capacitive sensor are embodied in comb-shaped fashion and are arranged in intermeshed fashion.

According to an embodiment, the comb-shaped electrodes of the capacitive sensor each have a cutout through which the flexure that couples the carrier plate and the base plate is guided. For example, the flexure is guided through the two cutouts of the comb-shaped electrodes of the capacitive sensor and hence connects the carrier plate and the base plate of the MEMS mirror. The mirror plate of the MEMS mirror is tiltable by the tilt angle by way of the flexure.

According to an embodiment, the mirror plate is connected to ground via a first resistor, and the upper electrode of the capacitive sensor is connected to ground via a second resistor.

As explained above, the MEMS mirror is displaceable in at least two tilt axes, such as in two mutually orthogonal tilt axes. In this case, for the purpose of displacing the mirror plate, at least two control units for actuating the mirror plate are provided per tilt axis.

According to an embodiment, the lithography apparatus has a voltmeter for measuring the electrical voltage dropped between the mirror plate and the base plate. In this case, the evaluation unit is configured to determine the position of the MEMS mirror via the measurement signals provided by the four sensor units and the measured electrical voltage.

According to an embodiment, the lithography apparatus has a micromirror array having a plurality of MEMS mirrors. The micromirror array can be part of an illumination system of the lithography apparatus.

According to an embodiment, the lithography apparatus comprises a vacuum housing, in which the radiation source, the MEMS mirror, the sensor units and the evaluation unit are arranged. For example, the vacuum housing is designed for a pressure of 1013.25 hPa to 10⁻³ hPa, such as 10⁻³ to 10⁻⁸ hPa, for example 10⁻⁸ to 10⁻¹¹ hPa, in its interior.

According to an embodiment, the lithography apparatus comprises a control device arranged externally to the vacuum housing and serving to control the radiation source via a control signal.

According to an embodiment, the MEMS mirror, the sensor units and the evaluation unit are arranged in the illumination system of the lithography apparatus.

According to an embodiment, the radiation source is an EUV radiation source.

The respective unit, for example the control unit, can be implemented in hardware and/or software. In the case of a hardware implementation, the unit can be embodied as a device or as part of a device, for example as a computer or as a microprocessor or as part of the control device. In the case of a software implementation, the unit can be embodied as a computer program product, as a function, as a routine, as part of a program code or as an executable object.

According to a second aspect, a method for operating a lithography apparatus is proposed. The lithography apparatus comprises a radiation source for generating radiation having a specific repetition frequency, and a MEMS mirror which is displaceable by a tilt angle in at least two tilt axes and serves for guiding the radiation in the lithography apparatus, which mirror comprises a capacitive sensor having a number of electrodes for capturing the tilt angle, wherein four sensor units are provided per tilt axis for the purpose of capturing a respective measurement signal from the capacitive sensor. The method comprises:
exciting the capacitive sensor via a first excitation signal V₁ by way of a first pair of the four sensor units and receiving a respective measurement signal I_{S1}, I_{S3} by way of each sensor unit of the first pair in response thereto;
exciting the capacitive sensor via a second excitation signal V₂ by way of a second pair of the four sensor units and receiving a respective measurement signal I_{S2}, I_{S4} by way of each sensor unit of the second pair in response thereto, wherein the first excitation signal V₁ and the second excitation signal V₂ have opposite polarities; and
determining the position of the MEMS mirror via the measurement signals I_{S1}-I_{S4} of the four sensor units.

Embodiments described for the proposed lithography apparatus according to the first aspect apply, mutatis mutandis, to the proposed method according to the second aspect.

Furthermore, the definitions and explanations in relation to the lithography apparatus also apply, mutatis mutandis, to the proposed method.

“A” or “an” or “one” in the present case should not necessarily be understood as restrictive to exactly one element. Rather, a plurality of elements, such as for example two, three or more, can also be provided. Nor should any other numeral used here be understood to the effect that there is a restriction to exactly the stated number of elements. Rather, numerical deviations upward and downward are possible, unless indicated otherwise.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject matter of the dependent claims and also of the exemplary embodiments of the disclosure that are described below. The disclosure is explained in greater detail hereinafter on the basis of various embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of one embodiment of an aspect of the lithography apparatus;

FIG. 3 shows a schematic sectional view of one embodiment of the sensor units of the lithography apparatus according to FIG. 2;

FIG. 4 shows a schematic view of one embodiment of the capture unit having sensor units and the evaluation unit of the lithography apparatus according to FIG. 2;

FIG. 5 shows a schematic view of a further embodiment of the capture unit having sensor units and the evaluation unit of the lithography apparatus according to FIG. 2;

FIG. 6 shows a schematic view of a further embodiment of the capture unit having sensor units and the evaluation unit of the lithography apparatus according to FIG. 2;

FIG. 7 shows one example of an excitation signal for exciting the capacitive sensor of the lithography apparatus;

FIG. 8 shows one example of a disturbing voltage, caused by the electrons dislodged by the radiation from the radiation source on the mirror plate;

FIG. 9 shows one example of a difference signal output by the evaluation unit according to FIG. 6;

FIG. 10 shows one example of a low-pass-filtered difference signal output by the low-pass filter according to FIG. 5; and

FIG. 11 shows one embodiment of a method for operating a lithography apparatus.

### EXEMPLARY EMBODIMENTS

In the figures, identical or functionally identical elements have been provided with the same reference signs, unless indicated otherwise. Furthermore, it should be noted that the illustrations in the figures are not necessarily true to scale.

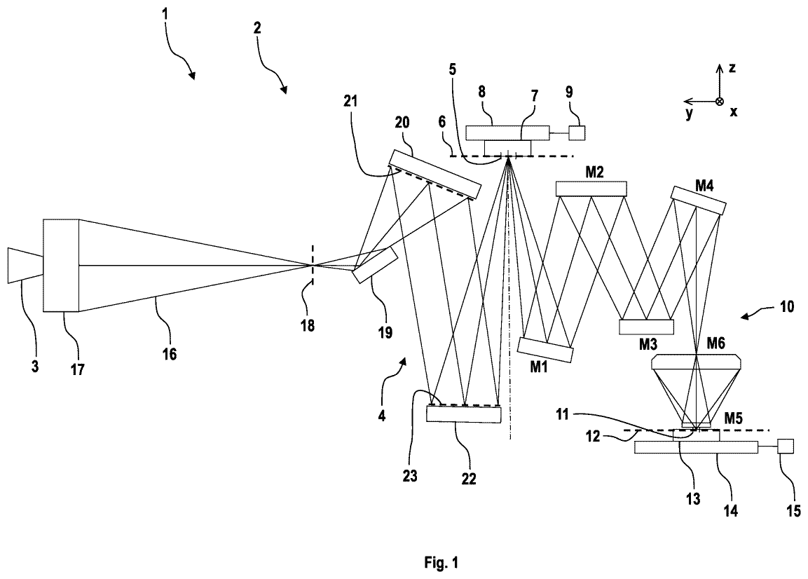

FIG. 1 shows one embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 depicts, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs along the y-direction y in FIG. 1. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement, firstly, of the reticle 7 by way of the reticle displacement drive 9 and, secondly, of the wafer 13 by way of the wafer displacement drive 15 can be synchronized with one another.

The light source 3 is an EUV radiation source. The light source 3 emits for example EUV radiation 16, which is also referred to below as used radiation, illumination radiation or illumination light. The used radiation 16 has for example a wavelength in the range of between 5 nm and 30 nm. The light source 3 can be a plasma source, for example an LPP (short for: laser produced plasma) source or a DPP (short for: gas-discharge produced plasma) source. It can also be a synchrotron-based radiation source. The light source 3 can be an FEL (short for: free-electron laser).

The illumination radiation 16 emanating from the light source 3 is focused by a collector 17. The collector 17 can be a collector with one or with a plurality of ellipsoidal and/or hyperboloidal reflection surfaces. The at least one reflection surface of the collector 17 can be impinged upon by the illumination radiation 16 with grazing incidence (abbreviated as: GI), that is to say with angles of incidence greater than 45°, or with normal incidence (abbreviated as: NI), that is to say with angles of incidence less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or alternatively a mirror with a beam-influencing effect going beyond the pure deflection effect. Alternatively or additionally, the deflection mirror 19 can be embodied as a spectral filter separating a used light wavelength of the illumination radiation 16 from extraneous light having a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 can be embodied as macroscopic facets, for example as rectangular facets or as facets with an arcuate or partly circular edge contour. The first facets 21 can be embodied as plane facets or alternatively as facets with convex or concave curvature.

As is known for example from DE 10 2008 009 600 A1, the first facets 21 themselves can also each be composed of a multiplicity of individual mirrors, for example a multiplicity of micromirrors. The first facet mirror 20 can be embodied for example as a microelectromechanical system (MEMS system). For details, reference is made to DE 10 2008 009 600 A1.

The illumination radiation 16 travels horizontally, i.e. along the y-direction y, between the collector 17 and the deflection mirror 19.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 can have plane or alternatively convexly or concavely curved reflection surfaces.

The illumination optical unit 4 thus forms a doubly faceted system. This fundamental principle is also referred to as a fly's eye condenser (or fly's eye integrator).

It can be desirable to arrange the second facet mirror 22 not exactly in a plane that is optically conjugate to a pupil plane of the projection optical unit 10. For example, the second facet mirror 22 can be arranged so as to be tilted in relation to a pupil plane of the projection optical unit 10, as described for example in DE 10 2017 220 586 A1.

The individual first facets 21 are imaged into the object field 5 with the aid of the second facet mirror 22. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing for example to the imaging of the first facets 21 into the object field 5 can be arranged in the beam path between the second facet mirror 22 and the object field 5. The transfer optical unit can comprise exactly one mirror, or alternatively two or more mirrors, which are arranged one behind the other in the beam path of the illumination optical unit 4. The transfer optical unit can for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20 and the second facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a passage opening for the illumination radiation 16. The projection optical unit 10 has an image-side numerical aperture that is greater than 0.5 and can also be greater than 0.6, and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, for example with alternating layers of molybdenum and silicon.

The projection optical unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

The projection optical unit 10 can be embodied for example in anamorphic fashion. For example, it has different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, i.e. in a direction perpendicular to the scanning direction.

The projection optical unit 10 leads to a reduction in size of 8:1 in the y-direction y, i.e. in the scanning direction.

Other imaging scales are also possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optical unit 10. Examples of projection optical units with different numbers of such intermediate images in the x-direction x and y-direction y are known from US 2018/0074303 A1.

In each case one of the second facets 23 is assigned to exactly one of the first facets 21 in order to form a respective illumination channel for illuminating the object field 5. For example, this can result in illumination according to the Köhler principle. The far field is decomposed into a multiplicity of object fields 5 with the aid of the first facets 21. The first facets 21 generate a plurality of images of the intermediate focus on the second facets 23 respectively assigned to them.

The first facets 21 are each imaged onto the reticle 7 by an assigned second facet 23 with images overlaid over one another for the purpose of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 can be defined geometrically by an arrangement of the second facets 23. The intensity distribution in the entrance pupil of the projection optical unit 10 can be set by selecting the illumination channels, for example the subset of the second facets 23 that guide light. This intensity distribution is also referred to as illumination setting or illumination pupil filling.

A likewise preferred pupil uniformity in the region of portions of an illumination pupil of the illumination optical unit 4 that are illuminated in a defined manner can be attained by a redistribution of the illumination channels.

Further aspects and details of the illumination of the object field 5 and for example of the entrance pupil of the projection optical unit 10 are described below.

The projection optical unit 10 can comprise for example a homocentric entrance pupil. The latter can be accessible. It can also be inaccessible.

The entrance pupil of the projection optical unit 10 regularly cannot be exactly illuminated using the second facet mirror 22. In the case of imaging by the projection optical unit 10 which telecentrically images the center of the second facet mirror 22 onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optical unit 10 has different positions of the entrance pupil for the tangential beam path and for the sagittal beam path. In this case, an imaging element, for example an optical component of the transfer optical unit, should be provided between the second facet mirror 22 and the reticle 7. With the aid of this optical element, the different position of the tangential entrance pupil and the sagittal entrance pupil can be taken into account.

In the arrangement of the components of the illumination optical unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

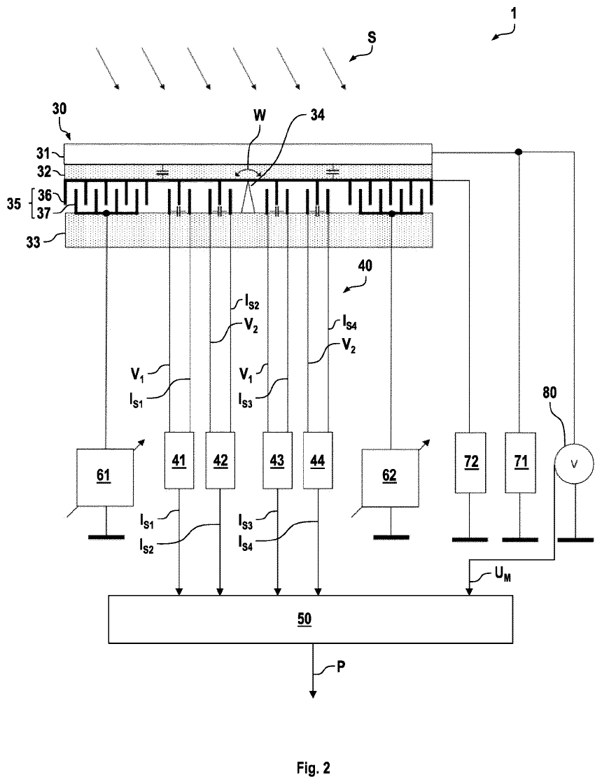

FIG. 2 shows a schematic view of one embodiment of an aspect of a lithography apparatus or projection exposure apparatus 1, as shown in FIG. 1, for example.

In this case, FIG. 2 shows the radiation S that is generated by the radiation source 3 of the lithography apparatus 1 according to FIG. 1 and has a specific repetition frequency. Furthermore, FIG. 2 shows a MEMS mirror 30 which is displaceable by a tilt angle W and serves for guiding the radiation S in the lithography apparatus 1. The MEMS mirror 30 can be for example part of one of the mirrors 20, 22, M1-M6 of the lithography apparatus 1 from FIG. 1.

The MEMS mirror 30 has a mirror plate 31 that is displaceable by the tilt angle W, a carrier plate 32 for carrying the mirror plate 31, a base plate 33, a flexure 34 that couples the carrier plate 32 and the base plate 33, and a capacitive sensor 35 having a number of electrodes 36, 37 that is arranged between the carrier plate 32 and the base plate 33.

As is furthermore illustrated in FIG. 2, the capacitive sensor 35 has an upper electrode 36 arranged in the direction of the mirror plate 31 and a lower electrode 37 arranged in the direction of the base plate 33 for measuring the tilt angle W of the mirror plate 31 of the MEMS mirror 30. In the example in FIG. 2, the upper electrode 36 is arranged on the carrier plate 32, whereas the lower electrode 37 is arranged on the base plate 33. The electrodes 36, 37 of the capacitive sensor 35 are embodied in comb-shaped fashion and arranged in intermeshed fashion. The comb-shaped electrodes 36, 37 of the capacitive sensor 35 each have a cutout through which the flexure 34 that couples the carrier plate 32 and the base plate 33 is guided.

The mirror plate 31 is connected to ground via a first resistor 71. Furthermore, the upper electrode 36 of the capacitive sensor 35 is connected to ground via a second resistor 72.

The MEMS mirror 30 is displaceable for example in two tilt axes, such as in two mutually orthogonal tilt axes. For the purpose of displacing the mirror plate 31, two control units 61, 62 for actuating the mirror plate 31 are provided per tilt axis.

In this context, the sectional view of the MEMS mirror 30 in FIG. 2 shows one tilt axis.

Four sensor units 41, 42, 43, 44 are provided per tilt axis for the purpose of capturing a respective measurement signal I_{S1}-I_{S4} from the capacitive sensor 35. The sensor units 41-44 form a capture device 40 for capturing the tilt angle W. In this case, a first pair of the four sensor units 41-44, for example formed by the sensor unit 41 and the sensor unit 43, is configured to excite the capacitive sensor 35 via a first excitation signal V₁ and to receive in response thereto a respective measurement signal I_{S1}, I_{S3}.

Consequently, the first pair is formed by the sensor unit 41 and the sensor unit 43. The sensor unit 41 excites the capacitive sensor 35 via the first excitation signal V₁ and receives in response thereto the measurement signal I_{S1}. Correspondingly, the sensor unit 43 excites the capacitive sensor 35 via the first excitation signal V₁ and receives in response thereto the measurement signal I_{S3}.

In embodiments, the excitation for the first sensor unit 41 and that for the third sensor unit 43 can be effected by a single first excitation signal V₁.

Furthermore, a second pair 42, 44 of the four sensor units 41-44, for example formed by the sensor unit 42 and the sensor unit 44, is configured to excite the capacitive sensor 35 via a second excitation signal V₂ and to receive in response thereto a respective measurement signal I_{S2}, I_{S4}.

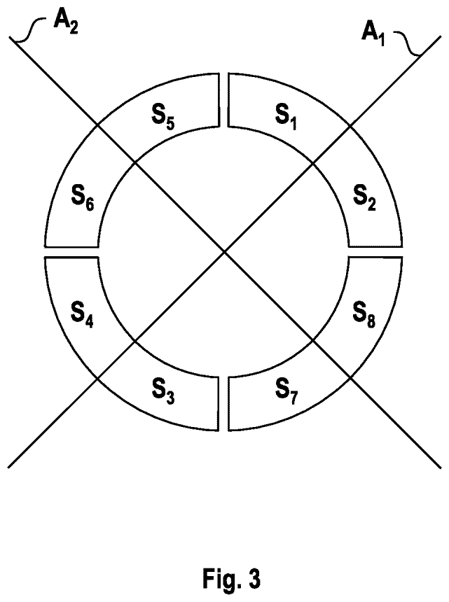

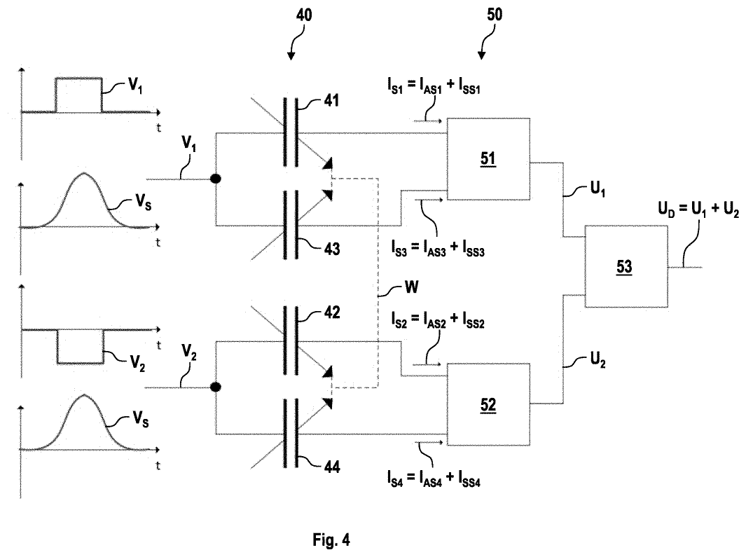

The sensor unit 42 and the sensor unit 44 form the second pair. In this case, the sensor unit 42 excites the capacitive sensor 35 via the second excitation signal V₂ and receives in response thereto the measurement signal I_{S2}. Correspondingly, the sensor unit 44 excites the capacitive sensor 35 via the second excitation signal V₂ and receives in response thereto the measurement signal I_{S4}. The first excitation signal V₁ and the second excitation signal V₂ have opposite polarities (in this respect, see for example FIG. 4, left hand part). The first excitation signal V₁ and the second excitation signal V₂ are embodied for example as excitation voltages having different polarities. The first excitation signal V₁ and the second excitation signal V₂ form a differential pair since they have opposite polarities. The respective measurement signal I_{S1}-I_{S4} is embodied for example as electric current.

The evaluation unit 50 connected downstream of the sensor units 41-44 in the lithography apparatus 1 according to FIG. 2 is configured to determine the position P of the MEMS mirror 30 via the measurement signals I_{S1}-I_{S4} of the four sensor units 41-44.

As is furthermore illustrated in FIG. 2, a voltmeter 80 can also be provided, which is configured to measure the electrical voltage U_{M} dropped between the mirror plate 31 and the base plate 33 (or ground). Since the base plate 33 is grounded, the voltmeter 80 can also be arranged between the mirror plate 31 and ground. Using the voltmeter 80, the evaluation unit 50 can also be configured to determine the position P of the MEMS mirror 30 via the measurement signals I_{S1}-I_{S4} provided by the four sensor units 41-44 and the measured electrical voltage U_{M}. This increases the accuracy in the determination of the position P of the MEMS mirror 30.

FIG. 3 shows a schematic sectional view of one embodiment of the sensor units of the lithography apparatus according to FIG. 2. FIG. 3 illustrates two tilt axes A₁, A₂ in which the MEMS mirror 30 according to FIG. 2 is displaceable. Each tilt axis A₁, A₂ is assigned four sensor units. Hence the tilt axis A₁ is assigned the sensor units S₁-S₄, whereas the tilt axis A₂ is assigned the sensor units S₅-S₈. Two of the sensor units respectively form a pair. For the tilt axis A₁, for example, the sensor units S₁ and S₃ form a first pair, whereas the sensor units S₂ and S₄ form a second pair. With reference to FIG. 2, therefore, the sensor unit S₁ in FIG. 3 corresponds to the sensor unit 41 in FIG. 2, the sensor unit S₂ in FIG. 3 corresponds to the sensor unit 42 in FIG. 2, the sensor unit S₃ in FIG. 3 corresponds to the sensor unit 43 in FIG. 2 and the sensor unit S₄ in FIG. 3 corresponds to the sensor unit 44 in FIG. 2.

FIG. 4 shows a schematic view of one embodiment of the capture unit 40 having the sensor units 41-44 and the evaluation unit 50 of the lithography apparatus 1 according to FIG. 2.

The sensor units 41-44 are illustrated as variable capacitances in FIG. 4. In this case, the capacitance of the respective sensor unit 41-44 changes by way of the tilt angle W, which is illustrated in FIG. 4 via the arrows through the capacitances 41-44, which are affected by the tilt angle W according to the dashed line in FIG. 4.

The left-hand region in FIG. 4 shows the first excitation signal V₁, the second excitation signal V₂ and the disturbing voltage V_{S} caused by the radiation S. The disturbing voltage V_{S} arises on the mirror surface of the MEMS mirror 30 by virtue of the incident radiation S dislodging electrons on the mirror surface of the MEMS mirror 30.

The disturbing voltage V_{S} causes the abovementioned disturbances at the respective output of the sensor units 41-44.

The first excitation signal V₁ is used to control the first pair comprising the sensor units 41, 43. The second excitation signal V₂ having opposite polarity is used to excite the second pair comprising the sensor units 42, 44. The disturbing voltage V_{S} is illustrated twice since it affects both the first pair comprising the sensor units 41, 43 and the second pair comprising the sensor units 42, 44.

The evaluation unit 50 according to FIG. 4 comprises a first converter 51, a second converter 52 and a subtractor 53. The first converter 51 is configured to receive the measurement signals I_{S1}, I_{S2} of the first pair 41, 43 of the sensor units and to provide on the output side a first voltage signal U₁ proportional to the difference between the received measurement signals I_{S1}, I_{S3}. The first converter 51 is embodied for example as a capacitance-voltage converter and can be referred to as first capacitance-voltage converter 51. The first capacitance-voltage converter 51 is configured to receive a first current I_{S1} at an input connected to the first sensor unit 41. The first current I_{S1} corresponds to a sum of the current I_{AS1} arising at the output of the first sensor unit 41 owing to the excitation of the capacitive sensor 35 with the first excitation signal V₁ and the current I_{SS1} arising at the output of the first sensor unit 41 owing to a disturbance caused by the radiation S on the MEMS mirror 30. In the reference sign I_{AS1}, I denotes an electric current, A denotes an excitation and S₁ denotes the first sensor unit 41 or S₁ (cf. FIG. 3). In the reference sign I_{SS1}, I denotes an electric current, S denotes a disturbance caused by the disturbing voltage V_{S} and S₁ denotes the first sensor unit 41 or S₁.

The first capacitance-voltage converter 51 is furthermore configured to receive a third current I_{S3} at an input connected to the third sensor unit 43, which third current corresponds to a sum of the current I_{AS3} arising at the output of the third sensor unit 43 owing to an excitation of the capacitive sensor 35 with the first excitation signal V₁ and the current I_{SS3} arising at the output of the third sensor unit 43 owing to a disturbance caused by the radiation S on the MEMS mirror 30. In the reference sign I_{AS3}, I denotes an electric current, A denotes an excitation and S₃ denotes the third sensor unit 43 or S₃. In the reference sign I_{SS3}, I denotes an electric current, S denotes a disturbance caused by the disturbing voltage V_{S} and S₃ denotes the third sensor unit 43 or S₃.

On the basis of the received currents I_{S1}, I_{S3}, the first capacitance-voltage converter 51 is configured to determine the first voltage signal U₁ according to equation (1) below and to output the first voltage signal on the output side. In this case, C_{INT} denotes the capacitance of the first capacitance-voltage converter 51.

$${U}_{1} = \frac{{\int }_{t 0}^{t 1} ( {I}_{AS 1} + {I}_{SS 1} ) dt}{{C}_{INT}} - \frac{{\int }_{t 0}^{t 1} ( {I}_{AS 3} + {I}_{SS 3} ) dt}{{C}_{INT}} \qquad ( 1 )$$

If the electric charges are considered instead of the electric currents I_{S1}, I_{S3}, then equation (1) above is also representable by equation (2) below.

$${U}_{1} = \frac{{Q}_{S 1} - {Q}_{S 3}}{{C}_{INT}} + \frac{{Q}_{SS 1} - {Q}_{SS 3}}{{C}_{INT}} \qquad ( 2 )$$

In this case, Q_{S1} denotes the charge provided at the output of the first sensor unit 41 or S₁ owing to the excitation with the first excitation signal V₁, Q_{S3} denotes the charge provided at the output of the third sensor unit 43 or S₃ owing to the excitation with the first excitation signal V₁, Q_{SS1} denotes the charge provided at the output of the first sensor unit 41 or S₁ on account of the disturbing voltage V_{S}, and Q_{SS3} denotes the charge provided at the output of the third sensor unit 43 or S₃ owing to the disturbing voltage V_{S}.

The second converter 52 is configured to receive the measurement signals I_{S2}, I_{S4} of the second pair 42, 44 of the sensor units and to provide on the output side a second voltage signal U₂ proportional to a difference between the received measurement signals I_{S2}, I_{S4}. The second converter 52, too, can be embodied as a capacitance-voltage converter and can be referred to as second capacitance-voltage converter 52.

The second capacitance-voltage converter 52 is configured to receive a second current I_{S2} at an input connected to the second sensor unit 42, which second current corresponds to a sum of the current I_{AS2} arising at the output of the second sensor unit 42 owing to an excitation of the capacitive sensor 35 with the second excitation signal V₂ and the current I_{SS3} arising at the output of the second sensor unit 42 owing to a disturbance caused by the radiation S on the MEMS mirror 30, to receive a fourth current I_{S4} at an input connected to the fourth sensor unit 44, which fourth current corresponds to a sum of the current I_{AS4} arising at the output of the fourth sensor unit 44 owing to an excitation of the capacitive sensor 35 with the second excitation signal V₂ and the current I_{SS4} arising at the output of the fourth sensor unit 44 owing to a disturbance caused by the radiation S on the MEMS mirror 30, and to determine the second voltage signal U₂ according to equation (3) below and to output the second voltage signal.

$${U}_{2} = \frac{{\int }_{t 0}^{t 1} ( {I}_{AS 2} + {I}_{SS 2} ) dt}{{C}_{INT}} - \frac{{\int }_{t 0}^{t 1} ( {I}_{AS 4} + {I}_{SS 4} ) dt}{{C}_{INT}} \qquad ( 3 )$$

In this case, C_{INT} denotes the capacitance of the second capacitance-voltage converter 52.

If the electric charges are considered instead of the electric currents I_{S2}, I_{S4}, then equation (3) above is also representable by equation (4) below.

$${U}_{2} = \frac{{Q}_{S 2} - {Q}_{S 4}}{{C}_{INT}} + \frac{{Q}_{SS 2} - {Q}_{SS 4}}{{C}_{INT}} \qquad ( 4 )$$

The subtractor 53 is configured to subtract the second voltage signal U₂ from the first voltage signal U₁ and depending thereon to output a difference signal U_{D} on the output side:

$${U}_{D} = {U}_{1} - {U}_{2} \qquad ( 5 )$$

Assuming that the disturbances caused by the incident radiation S (i.e. the respective disturbing voltages V_{S}) on the mutually adjacent sensor units 41-44 in FIGS. 2 and 4 (or S₁-S₄ in FIG. 3) are identical or approximately identical, the charges Q_{SS1}, Q_{SS2}, Q_{SS3} and Q_{SS4} are identical or almost identical. U_{D} can then be calculated as follows by way of equation (6) below:

$$\begin{matrix}{U}_{D} = {U}_{1} - {U}_{2} \\ = \frac{{Q}_{S 1} - {Q}_{S 3}}{{C}_{INT}} + \frac{{Q}_{SS 1} - {Q}_{SS 3}}{{C}_{INT}} + \frac{{Q}_{S 2} - {Q}_{S 4}}{{C}_{INT}} - \frac{{Q}_{SS 2} - {Q}_{SS 4}}{{C}_{INT}} \\ = \frac{{Q}_{S 1} - {Q}_{S 3}}{{C}_{INT}} + \frac{{Q}_{S 2} - {Q}_{S 4}}{{C}_{INT}}\end{matrix} \qquad ( 6 )$$

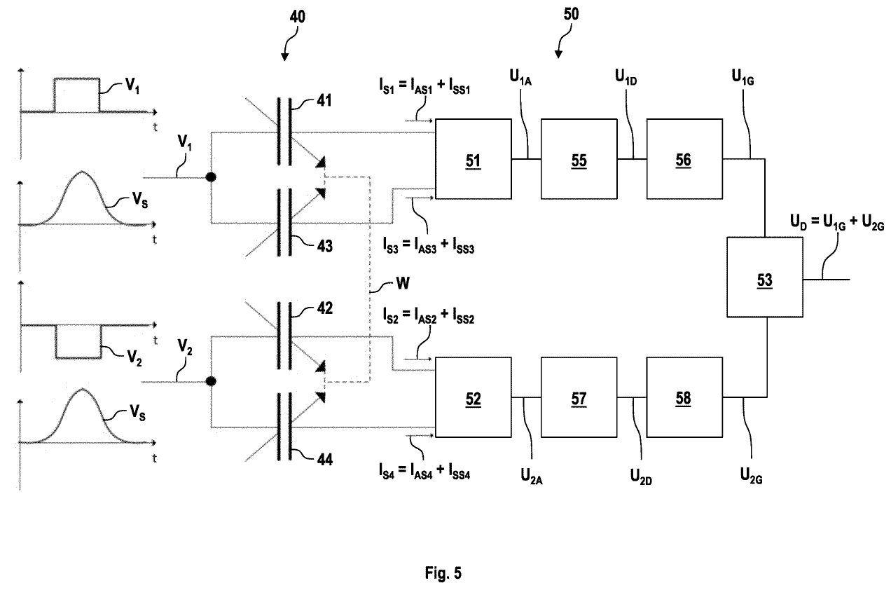

As shown by equation (6), the difference signal U_{D} has no signal components attributable to the disturbing voltage V_{S}, accordingly no Q_{SS1}, no Q_{SS2}, no Q_{SS3} and no Q_{SS4}. The evaluation unit 50 can then precisely determine the position P of the MEMS mirror 30 using the difference signal U_{D}. FIG. 5 shows a schematic view of a further embodiment of the capture unit 40 having sensor units 41-44 and the evaluation unit 50 of the lithography apparatus 1 according to FIG. 2. The embodiment according to FIG. 5 is substantially based on the embodiment according to FIG. 2 with the additional possibility of the individual adjustment of tolerances, with the result that the suppression of the EUV disturbance can be further improved. For this purpose, a first A/D converter 55 and a first weighting unit 56 are connected downstream of the first capacitance-voltage converter 51.

Correspondingly, a second A/D converter 57 and a second weighting unit 58 are connected downstream of the second capacitance-voltage converter 52.

The first A/D converter 55 is configured to convert the first voltage signal U_{1A} provided by the first capacitance-voltage converter 51 into a first digital voltage signal U_{1D}. The first weighting unit 56 is configured to weight the digital first voltage signal U_{1D} via an actual tilt angle—measured by a measuring unit (not shown)—of the MEMS mirror 30 in order to output a weighted first voltage signal U_{1G}.

The second A/D converter 57 is configured to convert the second voltage signal U_{2A} provided by the second capacitance-voltage converter 52 into a digital second voltage signal U_{2D}. The second weighting unit 58 is configured to weight the digital second voltage signal U_{2D} via the actual tilt angle—measured by the measuring unit—of the MEMS mirror 30 in order to output a weighted second voltage signal U_{2G}. The weighted first voltage signal U_{1G} and the weighted second voltage signal U_{2G} can take account of tolerances of the MEMS mirror 30, whereby the suppression of the EUV disturbance is further improved.

In this case, the subtractor 53 is configured to subtract the weighted second voltage signal U_{2G} from the weighted first voltage signal U_{1G} and depending thereon to output the difference signal Up on the output side. The difference signal Up can be used to determine the position P of the MEMS mirror 30.

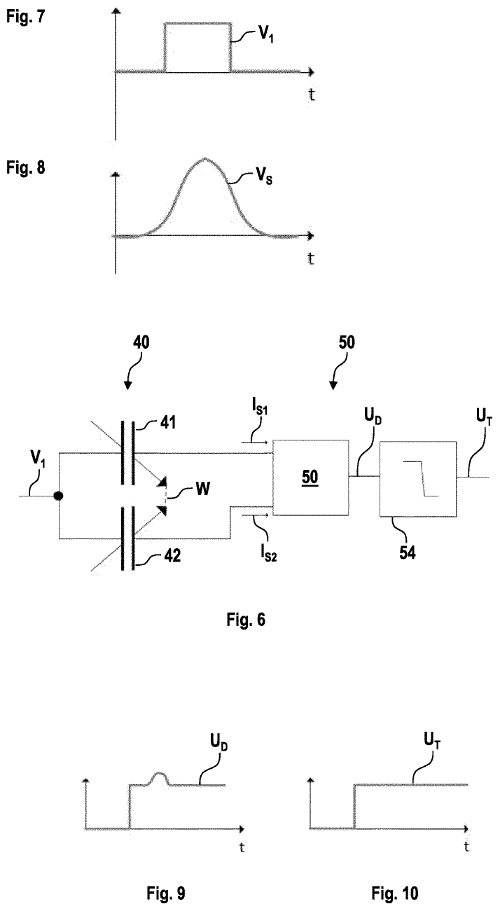

FIG. 6 shows a schematic view of a further embodiment of the capture device 40 having sensor units and the evaluation unit 50 of the lithography apparatus 1, for example according to FIG. 2. The embodiment according to FIG. 6 is substantially based on the embodiment according to FIG. 2 with the difference that the embodiment according to FIG. 6 manages with only two sensor units 41, 42 per tilt axis. According to FIG. 6, the capture device 40 for capturing the tilt angle W accordingly has two sensor units 41, 42 per tilt axis.

The sensor units 41, 42 are excited by an excitation signal V₁ according to FIG. 7. The disturbing voltage V_{S} according to FIG. 8 is caused by the electrons dislodged by the radiation S from the radiation source 3 on the mirror surface of the MEMS mirror 30 (cf. FIG. 2) and causes (analogously to the description regarding FIG. 4) an additional current at the output of the respective sensor unit 41, 42. As described analogously with reference to FIG. 4, the evaluation unit 50 according to FIG. 6 receives a first current I_{S1} from the sensor unit 41 and a second current I_{S2} from the sensor unit 42. The first current I_{S1} corresponds to a sum of the current arising at the output of the first sensor unit 41 owing to the excitation of the capacitive sensor 35 with the excitation signal V₁ according to FIG. 7 and the current arising at the output of the first sensor unit 41 owing to a disturbance (cf. FIG. 8) caused by the radiation S on the MEMS mirror 30.

Correspondingly, the second current I_{S2} corresponds to a sum of the current arising at the output of the second sensor unit 42 owing to the excitation of the capacitive sensor 35 with the excitation signal V₁ and the current arising at the output of the sensor unit 42 owing to the disturbance caused by the radiation S on the MEMS mirror 30. The evaluation unit 50 in FIG. 6 receives the currents I_{S1} and I_{S2} and depending thereon provides the difference signal Up on the output side. As is shown in FIG. 9, the difference signal U_{D} has high-frequency signal components attributable to the disturbing voltage V_{S}. The disturbance-affected difference signal U_{D} according to FIG. 9 is fed to the low-pass filter 54 according to FIG. 6, which filters out the high-frequency disturbances and outputs a low-pass-filtered difference signal U_{T} on the output side. The low-pass-filtered difference signal U_{T} can in turn be used to determine the position P of the MEMS mirror 30. This determination is precise since, in contrast to the difference signal Up according to FIG. 9, the low-pass-filtered difference signal U_{T} according to FIG. 10 does not have any disturbances caused by incident radiation S. As an alternative or in addition to the low-pass filter 54, it is possible to use a filter for discarding values with defined deviation.

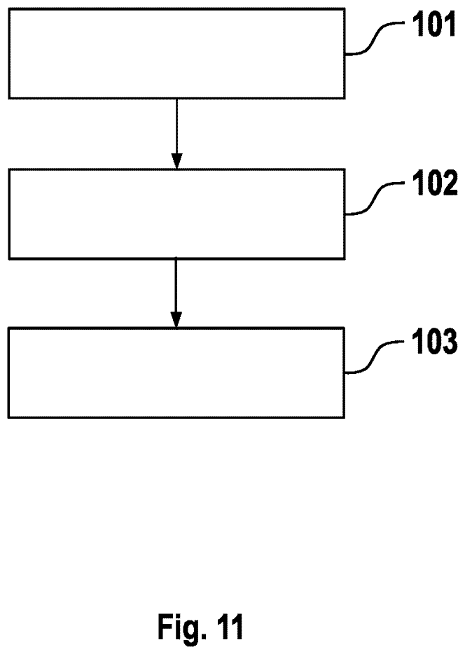

FIG. 11 shows a schematic diagram of a method for operating a lithography apparatus 1. The lithography apparatus 1 comprises a radiation source 3 for generating radiation S having a specific repetition frequency, a MEMS mirror 30 which is displaceable by a tilt angle W in at least two tilt axes A₁, A₂ and serves for guiding the radiation S in the lithography apparatus 1, which mirror comprises a capacitive sensor 35 having a number of electrodes 36, 37 for capturing the tilt angle W, wherein four sensor units 41-44 are provided per tilt axis A₁, A₂ for the purpose of capturing a respective measurement signal I_{S1}-I_{S4} from the capacitive sensor 35. The method according to FIG. 11 comprises steps 101-103. Steps 101 and 102 are carried out simultaneously, for example.

In step 101, the capacitive sensor 35 is excited via a first excitation signal V₁ by way of a first pair 41, 43 of the four sensor units 41-44 and in response thereto a respective measurement signal I_{S1}, I_{S3} is received by way of each sensor unit 41, 43 of the first pair.

In step 102, the capacitive sensor 35 is excited via a second excitation signal V₂ by way of a second pair 42, 44 of the four sensor units 41-44 and in response thereto a respective measurement signal I_{S2}, I_{S4} is received by way of each sensor unit 42, 44 of the second pair. The first excitation signal V₁ and the second excitation signal V₂ have opposite polarities.

In step 103, the position P of the MEMS mirror 30 is determined via the measurement signals I_{S1}-I_{S4} of the four sensor units 41-44.

Although the present disclosure has been described on the basis of exemplary embodiments, it is modifiable in diverse ways.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
30 Mirror
31 Mirror plate
32 Carrier plate
33 Base plate
34 Flexure
35 Capacitive sensor
36 Upper comb-shaped electrode
37 Lower comb-shaped electrode
40 Capture device
41 Sensor unit
42 Sensor unit
43 Sensor unit
44 Sensor unit
50 Evaluation unit
51 Converter, Capacitance-voltage converter
52 Converter, Capacitance-voltage converter
53 Subtractor
54 Low-pass filter
55 A/D converter
56 Weighting unit
57 A/D converter
58 Weighting unit
61 Control unit
62 Control unit
71 Resistor
72 Resistor
80 Voltmeter
101 Step
102 Step
103 Step
A₁ Tilt axis
A₂ Tilt axis
I_{AS1} Current at the output of the first sensor unit owing to the excitation with excitation signal
I_{AS2} Current at the output of the second sensor unit owing to the excitation with excitation signal
I_{AS3} Current at the output of the third sensor unit owing to the excitation with excitation signal
I_{AS4} Current at the output of the fourth sensor unit owing to the excitation with excitation signal
I_{SS1} Current at the output of the first sensor unit owing to EUV disturbance
I_{SS2} Current at the output of the second sensor unit owing to EUV disturbance
I_{SS3} Current at the output of the third sensor unit owing to EUV disturbance
I_{SS4} Current at the output of the fourth sensor unit owing to EUV disturbance
M1 Mirror
M2 Mirror
M3 Mirror
M4 Mirror
M5 Mirror
M6 Mirror
P Position of the mirror
S Radiation
S₁ Sensor unit
S₂ Sensor unit
S₃ Sensor unit
S₄ Sensor unit
U_{D} Difference signal
U_{T} Low-pass-filtered difference signal
U₁ First voltage signal
U_{1A} Analog first voltage signal
U_{1D} Digital first voltage signal
U_{1G} Weighted first voltage signal
U₂ Second voltage signal
U_{2A} Analog second voltage signal
U_{2D} Digital second voltage signal
U_{2G} Weighted second voltage signal
U_{M} Voltage between mirror plate and base plate
V₁ First excitation signal
V₂ Second excitation signal
V_{S} Disturbing voltage (disturbance owing to incident radiation)
W Tilt angle

1. A lithography apparatus, comprising:
a radiation source configured to generate radiation having a repetition frequency;
a MEMS mirror which is displaceable by a tilt angle in first and second tilt axes, the MEMS mirror configured to guide the radiation in the lithography apparatus;
a first group of four sensor units for the first tilt axis, each sensor unit of the first group of sensor units configured to capture a respective measurement signal;
a second group of four sensor units for the second tilt axis, each sensor unit of the second group of sensor units configured to capture a respective measurement signal; and
an evaluation unit,
wherein:
the MEMS mirror comprises a capacitive sensor comprising electrodes configured to capture the tilt angle;
for each of the first and second groups of four sensor units, the four sensor units comprises a first pair of sensor units and a second pair of sensor units;
for each of the first and second groups of four sensor units, the first pair of sensor units is configured to excite the capacitive sensor via a first excitation signal and to receive in response thereto the respective measurement signal of each of the two sensor units of the first pair of sensor units;
for each of the first and second groups of four sensor units, the second pair of sensor units is configured to excite the capacitive sensor via a second excitation signal and to receive in response thereto the respective measurement signal of each of the two sensor units of the second pair of sensor units;
for each first and second groups of four sensor units, a polarity of the first excitation signal is opposite to a polarity of the second excitation signal; and
the evaluation unit is configured to determine a position of the MEMS mirror via the measurement signals of each of the first and second groups of four sensor units,
wherein the evaluation unit comprises:
a first converter configured to, for the first pair of sensor units of each the first and second groups of four sensor units:
i) receive the measurement signals of the first pair of sensor units; and
ii) provide, on an output side of the evaluation unit, a first voltage signal proportional to a difference between the received measurement signals;
a second converter configured to, for the second pair of sensor units of each the first and second groups of four sensor units:
i) receive the measurement signals of the second pair of the sensor units; and
ii) provide, on the output side of the evaluation unit, a second voltage signal proportional to a difference between the received measurement signals; and
a subtractor configured to, for each of the first and second groups of four sensor units:
i) subtract the second voltage signal from the first voltage signal; and
ii) provide, on the output side of the evaluation unit, a difference signal based on the difference between the second and first voltage signals, and
wherein, for each of the first and second groups of four sensor units:
the first converter comprises a first capacitance-voltage converter configured to obtain a first current at an input connected to the first sensor unit, which first current corresponds to a sum of the current (I_{AS1}) arising at the output of the first sensor unit owing to an excitation of the capacitive sensor with the first excitation signal and the current (I_{SS1}) arising at the output of the first sensor unit owing to a disturbance caused by the radiation on the MEMS mirror, to obtain a third current at an input connected to the third sensor unit, which third current corresponds to a sum of the current (I_{AS3}) arising at the output of the third sensor unit owing to an excitation of the capacitive sensor with the first excitation signal and the current (I_{SS3}) arising at the output of the third sensor unit owing to a disturbance caused by the radiation on the MEMS mirror, and to determine the first voltage signal (U₁) according to the equation
$${U}_{1} = \frac{{\int }_{t 0}^{t 1} ( {I}_{AS 1} + {I}_{SS 1} ) dt}{{C}_{INT}} - \frac{{\int }_{t 0}^{t 1} ( {I}_{AS 3} + {I}_{SS 3} ) dt}{{C}_{INT}}$$
and to output said first voltage signal, wherein C_{INT} denotes the capacitance of the first capacitance-voltage converter.

2. The lithography apparatus of claim 1, wherein the evaluation unit comprises a differential evaluation unit.

3.-4. (canceled)

5. The lithography apparatus of claim 1, wherein, for each of the first and second groups of four sensor units:
the second converter comprises a second capacitance-voltage converter configured to obtain a second current at an input connected to the second sensor unit, which second current corresponds to a sum of the current (I_{AS2}) arising at the output of the second sensor unit owing to an excitation of the capacitive sensor with the second excitation signal and the current (I_{SS2}) arising at the output of the second sensor unit owing to a disturbance caused by the radiation on the MEMS mirror, to obtain a fourth current at an input connected to the fourth sensor unit, which fourth current corresponds to a sum of the current (I_{AS4}) arising at the output of the fourth sensor unit owing to an excitation of the capacitive sensor with the second excitation signal (V₂) and the current (I_{SS4}) arising at the output of the fourth sensor unit owing to a disturbance caused by the radiation on the MEMS mirror, and to determine the second voltage signal (U₂) according to the equation
$${U}_{2} = - \frac{{\int }_{t 0}^{t 1} ( {I}_{AS 2} + {I}_{SS 2} ) dt}{{C}_{INT}} - \frac{{\int }_{t 0}^{t 1} ( {I}_{AS 4} + {I}_{SS 4} ) dt}{{C}_{INT}}$$
and to output said second voltage signal, wherein C_{INT} denotes the capacitance of the second capacitance-voltage converter.

6. The lithography apparatus of claim 1, wherein the evaluation unit is configured to determine the position of the MEMS mirror based on the difference signal.

7. The lithography apparatus of claim 1, further comprising:
a first A/D converter and a first weighting unit connected downstream of the first converter; and
a second A/D converter and a second weighting unit are connected downstream of the second converter,
wherein:
the first A/D converter is configured to convert the first voltage signal provided by the first converter into a first digital voltage signal;
the first weighting unit is configured to weight the digital first voltage signal via an actual measured tilt angle measured to output a weighted first voltage signal; a
the second A/D converter is configured to convert the second voltage signal provided by the second converter into a digital second voltage signal;
the second weighting unit is configured to weight the digital second voltage signal via the actual measured tilt angle of the MEMS mirror to output a weighted second voltage signal; and
the subtractor is configured to subtract the weighted second voltage signal from the weighted first voltage signal and depending thereon to output the difference signal on the output side.

8. The lithography apparatus of claim 1, further comprising a calibration unit,
wherein:
each of the first and second converters comprises a trimmable capacitor; and
the calibration unit is provided is configured to trim a respective trimmable capacitor via an actual measured tilt angle of the MEMS mirror.

9. (canceled)

10. The lithography apparatus of claim 1, wherein the MEMS mirror comprises:
a mirror plate that is displaceable by the tilt angle;
a carrier plate configured to carry the mirror plate;
a base plate;
a flexure coupling the base plate and the carrier plate, the flexure configured to tilt the mirror plate; and
the capacitive sensor.

11. The lithography apparatus of claim 10, wherein the capacitive sensor comprises an upper electrode and a lower electrode,
wherein:
the lower electrode is between the upper electrode and the base plate; and
the lower electrode is configured to measure a tilt angle of the mirror plate.

12. The lithography apparatus of claim 11, wherein each of the comb-shaped electrodes has a cutout through which the flexure extends.

13. The lithography apparatus of claim 10, wherein each of the upper and lower electrodes is comb-shaped, and the upper and lower electrodes are intermeshed with each other.

14. The lithography apparatus of claim 10, further comprising, for each of the first and second tilt axes, at least control units configured to actuate the mirror plate to displace the mirror plate.

15. The lithography apparatus of claim 10, further comprising a voltmeter configured to measure an electrical voltage dropped between the mirror plate and the base plate, wherein the evaluation unit is configured to determine the position of the MEMS mirror via the measurement signals provided by the four sensor units and the measured electrical voltage.

16. The lithography apparatus of claim 10, wherein the evaluation unit comprises a differential evaluation unit.

17. The lithography apparatus of claim 1, wherein the lithography apparatus comprises a micromirror array comprising a plurality of MEMS mirrors.

18. The lithography apparatus of claim 17, wherein the lithography apparatus comprises an illumination system, and the illumination system comprises a micromirror array which comprises a plurality of MEMS mirrors.

19. The lithography apparatus of claim 17, wherein the evaluation unit comprises a differential evaluation unit.

20. A method of operating a lithography apparatus comprising a radiation source that generates radiation having a repetition frequency, a MEMS mirror which is displaceable by a tilt angle in first and second tilt axes guides the radiation in the lithography apparatus, the MEMS mirror comprising a capacitive sensor comprising electrodes that capture the tilt angle, wherein four sensor units are provided for each of the first and second tilt axes to capture a respective measurement signal from the capacitive sensor (35), the method comprising for each of the first and second tilt axes:
exciting the capacitive sensor via a first excitation signal via a first pair of the four sensor units and receiving a respective measurement signal by way of each sensor unit of the first pair in response thereto;
exciting the capacitive sensor via a second excitation signal via a second pair of the four sensor units and receiving a respective measurement signal via each sensor unit of the second pair in response thereto, the first excitation signal and the second excitation signal having opposite polarities; and
determining a position of the MEMS mirror based on the measurement signals of the four sensor units using an evaluation unit which comprises:
a first converter configured to, for the first pair of sensor units of each the first and second groups of four sensor units:
i) receive the measurement signals of the first pair of sensor units; and
ii) provide, on an output side of the evaluation unit, a first voltage signal proportional to a difference between the received measurement signals;
a second converter configured to, for the second pair of sensor units of each the first and second groups of four sensor units:
i) receive the measurement signals of the second pair of the sensor units; and
ii) provide, on the output side of the evaluation unit, a second voltage signal proportional to a difference between the received measurement signals; and
a subtractor configured to, for each of the first and second groups of four sensor units:
i) subtract the second voltage signal from the first voltage signal; and
ii) provide, on the output side of the evaluation unit, a difference signal based on the difference between the second and first voltage signals, and
wherein, for each of the first and second groups of four sensor units:
the first converter comprises a first capacitance-voltage converter configured to obtain a first current at an input connected to the first sensor unit, which first current corresponds to a sum of the current (I_{AS1}) arising at the output of the first sensor unit owing to an excitation of the capacitive sensor with the first excitation signal and the current (I_{SS1}) arising at the output of the first sensor unit owing to a disturbance caused by the radiation on the MEMS mirror, to obtain a third current at an input connected to the third sensor unit, which third current corresponds to a sum of the current (I_{AS3}) arising at the output of the third sensor unit owing to an excitation of the capacitive sensor with the first excitation signal and the current (I_{SS3}) arising at the output of the third sensor unit owing to a disturbance caused by the radiation on the MEMS mirror, and to determine the first voltage signal (U₁) according to the equation
$${U}_{1} = \frac{{\int }_{t 0}^{t 1} ( {I}_{AS 1} + {I}_{SS 1} ) dt}{{C}_{INT}} - \frac{{\int }_{t 0}^{t 1} ( {I}_{AS 3} + {I}_{SS 3} ) dt}{{C}_{INT}}$$
and to output said first voltage signal, wherein C_{INT} denotes the capacitance of the first capacitance-voltage converter.

21. The method of claim 20, wherein the lithography apparatus comprises a micromirror array comprising a plurality of MEMS mirrors.

22. The method of claim 21, wherein the lithography apparatus comprises an illumination system, and the illumination system comprises a micromirror array which comprises a plurality of MEMS mirrors.

23. The method of claim 21, wherein the evaluation unit comprises a differential evaluation unit.
